(19) United States
(12) Patent Application Publication
(10) Pub. No.: US 2026/0371943 A1
(43) Pub. Date: Nov. 19, 2026

(54) ELECTROCHEMICAL MEMORY DEVICE

(71) Applicant: SK hynix Inc., Icheon-si (KR)

(72) Inventor: Young Jae KWON, Icheon-si (KR)

(21) Appl. No.: 19/679,040

(22) Filed: May 15, 2026

(30) Foreign Application Priority Data
May 15, 2025 (KR) 10-2025-0063472

(51) Int. Cl. H10N 70/00; H10B 63/00; H10N 70/20

(52) U.S. Cl. CPC H10N 70/8613; H10B 63/30; H10N 70/011; H10N 70/253

(57) ABSTRACT

A memory device includes: a channel region disposed over a semiconductor substrate; a gate stack disposed over the channel region; an insulation layer configured to contact sidewalls of the channel region and the gate stack; and a heating layer configured to contact sidewalls of the insulation layer.

### CROSS-REFERENCE TO RELATED APPLICATION

This patent document claims the priority under 35 U.S.C. §119(a) and the benefits of Korean patent application No. 10-2025-0063472, filed on May. 15, 2025, the disclosure of which is incorporated herein by reference in its entirety as part of the disclosure of this patent document.

### TECHNICAL FIELD

The technology and implementations disclosed in this patent document generally relate to an electrochemical memory device, and more particularly to an electrochemical memory device with improved operating speed.

### BACKGROUND

A neuromorphic system refers to a system that mimics a data processing method of the brain by applying the operational principles and structural characteristics of nerve cells (neurons). A synaptic device implementing the neuromorphic system is interconnected with other synaptic devices in a similar way to such neurons, so that the synaptic device can store, integrate, and output data.

A crossbar memory structure employed in neuromorphic systems utilizes two-terminal memory devices, such as resistive random access memory (ReRAM), conductive bridging random access memory (CBRAM), or phase-change random access memory (PRAM), as synaptic devices. This crossbar memory structure offers advantages of a simple configuration and a highly dense device array.

Each of two-terminal memory devices uses one terminal thereof as a ground, and receives a voltage pulse through the other terminal thereof. The two-terminal memory devices are designed to perform neural network learning (also called “neural network training”) by using an internal resistance value of each memory device as a weight. Here, the internal resistance value of the memory device may vary depending on voltage pulses. However, when verification of the trained memory structures in the two-terminal memory devices is performed, the internal resistance value of each memory device may vary depending on a voltage to be applied to the memory device for such memory verification.

A three-terminal neuromorphic system based on an electrochemical random access memory (ECRAM) device, which further includes a gate terminal to control the amount of current flowing between a source terminal and a drain terminal, is designed such that active ions flow into internal memory devices of the three-terminal neuromorphic system during a write operation and the internal resistance of the memory devices are changed. As a result, variation in the resistance value of the memory device may be reduced, and operation stability of the memory device is improved.

### SUMMARY

Various embodiments of the present disclosure relate to an electrochemical memory device including a heating circuit to facilitate the migration of active ions and improve the operating speed of electrochemical memory device.

In accordance with an embodiment of the present disclosure, a memory device may include: a channel region disposed over a semiconductor substrate; a gate stack disposed over the channel region; an insulation layer configured to contact sidewalls of the channel region and the gate stack; and a heating layer configured to contact sidewalls of the insulation layer.

In some implementations, the memory device may further include: a source region and a drain region disposed within the channel region and spaced apart from each other.

In some implementations, the heating layer may include a resistive material.

In some implementations, the insulation layer has an upper portion thereof that is wider than a lower portion.

In some implementations, when a heating voltage is applied to the heating layer, the heating layer may generate Joule heat.

In some implementations, the insulation layer has an upper portion with the same width as a lower portion.

In some implementations, the gate stack may include: an electrolyte layer disposed over the channel region; an ion storage layer disposed over the electrolyte layer; and a gate electrode layer disposed over the ion storage layer.

In some implementations, active ions in the ion storage layer may include at least one of hydrogen ions, lithium ions, or oxygen ions.

In some implementations, when a gate voltage is applied to the gate stack and the applied gate voltage is equal to or greater than a threshold voltage, the active ions may move from the gate stack to the channel region.

In accordance with another embodiment of the present disclosure, a method for manufacturing a memory device may include: forming a channel region over a semiconductor substrate; forming a gate stack over the channel region; forming an insulation layer in contact with sidewalls of the channel region and the gate stack; and forming a heating layer in contact with sidewalls of the insulation layer.

In some implementations, the method may further include: forming a source region and a drain region spaced apart from each other within the channel region.

In some implementations, the forming the insulation layer may include: depositing the insulation layer; and etching at least a portion of the insulation layer such that a width of an upper portion of the insulation layer is greater than a width of a lower portion of the insulation layer.

In some implementations, the forming the gate stack may include: forming an electrolyte layer over the channel region; forming an ion storage layer over the electrolyte layer; and forming a gate electrode layer over the ion storage layer.

It is to be understood that both the foregoing general description and the following detailed description of the present disclosure are illustrative and explanatory and are intended to provide further explanation of the disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is an equivalent circuit diagram illustrating a memory device array including a plurality of memory devices according to an embodiment of the present disclosure.

FIG. 2 is a schematic diagram illustrating a memory device array according to an embodiment of the present disclosure.

FIG. 3 is a cross-sectional view illustrating a memory device according to an embodiment of the present disclosure.

FIGS. 4A and 4B are views illustrating a method for operating a three-terminal memory device according to an embodiment of the present disclosure.

FIG. 5 is a cross-sectional view illustrating a memory device according to another embodiment of the present disclosure.

FIGS. 6A-6F are views illustrating a method for manufacturing a memory device according to an embodiment of the present disclosure.

FIGS. 7A-7G are views illustrating a method for manufacturing a memory device according to another embodiment of the present disclosure.

### DETAILED DESCRIPTION

This patent document provides implementations and examples of an electrochemical memory device with improved operating speed, that may be used in configurations to substantially address one or more technical or engineering issues and to mitigate limitations or disadvantages encountered in other electrochemical memory devices. Some implementations of the present disclosure relate to an electrochemical memory device including a heating circuit to facilitate the migration of active ions and improve the operating speed of electrochemical memory device. In recognition of the issues above, the present disclosure may provide the electrochemical memory device including the heating circuit so that the operating speed of the memory device can be increased. The memory device array including the electrochemical memory device according to embodiments of the present disclosure may also reduce power consumption required for neuromorphic computation, thereby enabling low-power and high-efficiency on-device training.

Reference will now be made in detail to the embodiments of the present disclosure, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

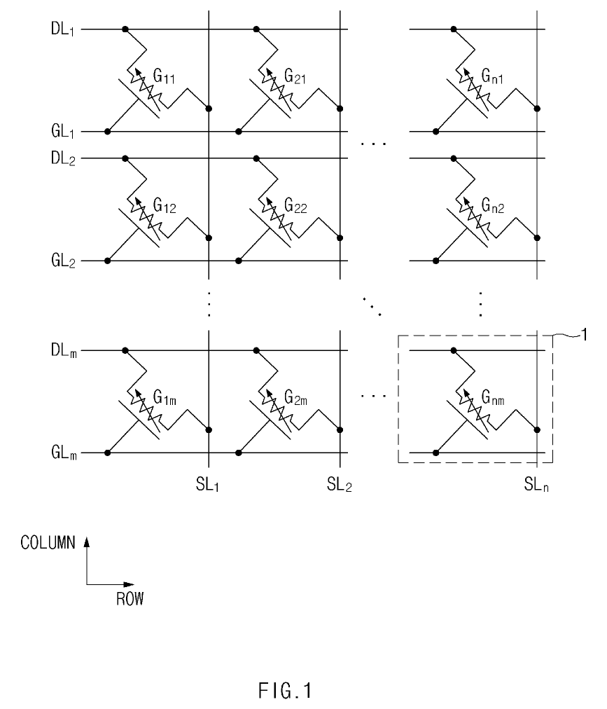

FIG. 1 is an equivalent circuit diagram illustrating a memory device array including a plurality of memory devices according to an embodiment of the present disclosure.

Referring to FIG. 1, a memory device array may be a synaptic array capable of performing artificial neural network training.

Each of a plurality of memory devices 1 included in the memory device array may include a source terminal, a drain terminal, and a gate terminal.

The gate terminals included in the memory devices 1 may be connected to gate lines (GL₁, GL₂ to GLₘ), respectively. In addition, the source terminal of the memory device 1 may be connected to each of a plurality of source lines (SL₁, SL₂ to SLₙ) repeatedly arranged in a row direction, and the drain terminal of the memory device 1 may be connected to a plurality of drain lines (DL₁, DL₂ to DLₘ) repeatedly arranged in a column direction.

The memory devices 1 may be individually programmed to have different conductances (Gᵢⱼ). For example, when programming a specific memory device 1 from among the plurality of memory devices 1, a programming voltage may be selectively applied to a gate line (GLⱼ) and a source line (SLᵢ), thereby changing the conductance (Gᵢⱼ) of the memory device 1.

The conductance (Gᵢⱼ) stored in each memory device 1 may be accessed by measuring the conductance (Gᵢⱼ) between a drain line (DLⱼ) and a source line (SLᵢ).

Matrix computation using the memory device array may be performed using the conductance values (Gᵢⱼ) respectively stored in the plurality of memory devices 1 included in the memory device array.

More specifically, the memory device array may store a matrix corresponding to a set of conductance values (Gᵢⱼ), and the stored matrix may serve as a weight matrix for artificial neural network training. When an arbitrary input is provided to the memory device array, a multiplication and accumulation (MAC) operation value based on the stored matrix may be output from the memory device array.

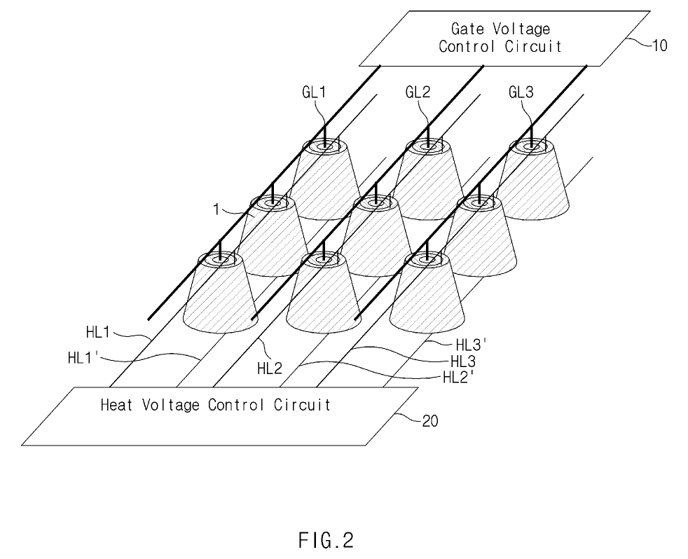

FIG. 2 is a schematic diagram illustrating a memory device array according to an embodiment of the present disclosure.

FIG. 2 illustrates memory devices 1, gate lines (GL1, GL2, GL3) connected to the memory devices 1, and heating lines (HL1, HL1’, HL2, HL2’, HL3, HL3’) connected to the memory devices 1. In addition, a gate voltage control circuit 10 is connected to the gate lines (GL1, GL2, GL3) and a heat voltage control circuit 20 is connected to the heating lines (HL1, HL1’, HL2, HL2’, HL3, HL3’).

In some embodiments, each of the plurality of memory devices 1 arranged over the memory device array may share its gate line (e.g., GL1, GL2, GL3) with adjacent memory devices 1. The gate voltage control circuit 10 may provide a gate voltage to any of the memory devices 1 through the respective gate lines (GL1, GL2, GL3).

Each of the gate lines (GL1, GL2, GL3) may be connected to a gate electrode of a memory device 1, and the conductance of the memory device 1 may be changed and stored according to the voltage applied to the gate electrode.

Each memory device 1 may be electrically connected to a pair of heating lines (for example, HL1 and HL1’).

The heating lines (HL1, HL1’, HL2, HL2’, HL3, HL3’) may extend in the same direction as the gate lines (GL1, GL2, GL3).

As described in more detail below, a pair of heating lines (for example, HL1 and HL1’) may be connected to both ends of a heating terminal included in the memory device 1. The memory device 1 may include a heating layer disposed between the heating terminals, and a voltage may be provided to both ends of the heating layer through the heating lines (for example, HL1 and HL1’). The voltage applied through the heating lines (for example, HL1 and HL1’) may cause a current to flow through the heating layer, and Joule heating may occur in the heating layer.

The voltage applied to the heating lines (HL1, HL1’, HL2, HL2’, HL3, HL3’) may be determined by the heat voltage control circuit 20.

When Joule heating occurs in the heating layer, the mobility of active ions included in the memory device 1 may increase. When the mobility of the active ions increases, the diffusion speed of the active ions becomes higher, so that the conductance of the memory device 1 can be more rapidly stabilized.

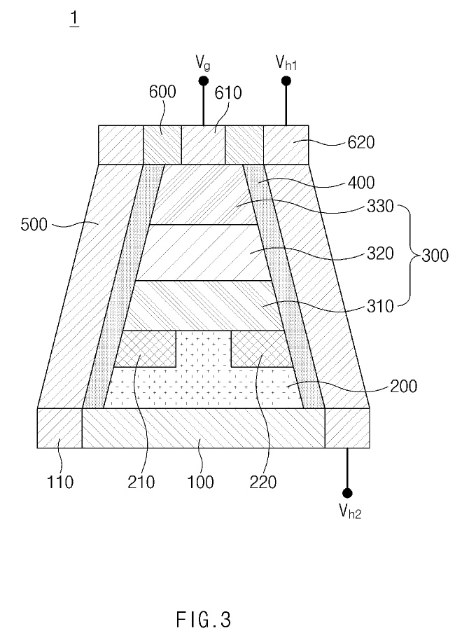

FIG. 3 is a cross-sectional view illustrating a memory device according to an embodiment of the present disclosure.

Referring to FIG. 3, in a memory device 1, a channel region 200 is disposed in a first direction (e.g., a vertical direction) over a substrate 100, and a gate stack 300 may be disposed over the channel region 200. An insulation layer 400 may be in contact with sidewalls of the channel region 200 and the gate stack 300, and a heating layer 500 may be in contact with sidewalls of the insulation layer 400.

A spacer layer 600 may be positioned in the first direction over the gate stack 300, the insulation layer 400, and the heating layer 500.

A gate terminal 610 may be disposed at a first side of the the spacer layer 600. A first heating terminal 620 may be disposed at a second side of the spacer layer 600. A source region 210 and a drain region 220, which are spaced apart from each other in a second direction (e.g., a horizontal direction), may be disposed within the channel region 200. A second heating terminal 110 may be disposed within the substrate 100.

The gate stack 300 may include an electrolyte layer 310 disposed over the channel region 200, an ion storage layer 320 disposed over the electrolyte layer 310, and a gate electrode layer 330 disposed over the ion storage layer 320.

The substrate 100 may be a silicon substrate, a silicon-on-insulator (SOI) substrate, a germanium substrate, a germanium-on-insulator (GOI) substrate, or a silicon-germanium substrate. For example, the substrate 100 may be a silicon substrate doped with P-type or N-type impurities.

The channel region 200 may include a material having conductance that varies depending on active ions. For example, the channel region 200 may include an organic semiconductor, a conductive polymer, an inorganic semiconductor, an oxide semiconductor, a two-dimensional (2D) semiconductor, or a metallic material such as tungsten (W), cobalt (Co), molybdenum (Mo), titanium (Ti), or tantalum (Ta).

The channel region 200 may include a material in which conductance increases upon receiving active ions. For example, the channel region 200 may include WO₃, TiO₂, ZrO₂, ZnO, or PCMO (Pr₁₋ₓCaₓMnO₃).

The source region 210 and the drain region 220 disposed in the channel region 200 may include a conductive material. The conductive material may include, for example, at least one of aluminum, copper, nickel, iron, chromium, titanium, zinc, lead, gold, or silver. According to another embodiment, the source region 210 and the drain region 220 may include a doped polymer material or a conductive polymer material. The source region 210 and the drain region 220 may be connected to a source terminal and a drain terminal, respectively.

The gate stack 300 may include a plurality of layers. The gate stack 300 may include an electrolyte layer 310 disposed over the channel region 200. The electrolyte layer 310 may be a layer containing an electrolyte, which allows active ions to pass easily through the layer while restricting the flow of electric current, and as a result the electrolyte layer 310 can prevent or reduce current leakage.

The gate stack 300 may include an ion storage layer 320 disposed over the electrolyte layer 310. The ion storage layer 320 may be a layer in which active ions are generated. Depending on the gate voltage applied to the gate stack 300, the active ions generated in the ion storage layer 320 may move through the electrolyte layer 310 into the channel region 200, or the active ions in the channel region 200 may move back into the ion storage layer 320.

The gate stack 300 may include a gate electrode layer 330 disposed over the ion storage layer 320. The gate electrode layer 330 may include a metallic material, which may include, for example, at least one of aluminum, copper, nickel, iron, chromium, titanium, zinc, lead, gold, or silver. The gate stack 300 may receive a gate voltage through a gate terminal 610.

The channel region 200 and the gate stack 300 disposed over the substrate 100 may have a frustum (or truncated cone) shape.

The insulation layer 400 may have a shape surrounding the sidewalls of the channel region 200 and the gate stack 300. The insulation layer 400 may electrically isolate the channel region 200 and the gate stack 300 from the heating layer 500. The insulation layer 400 may include, for example, silicon oxide, silicon nitride, and the like.

The heating layer 500 may have a shape surrounding the sidewalls of the insulation layer 400. The heating layer 500 may include a resistive material capable of generating Joule heat in response to the received heating voltage. The material included in the heating layer 500 may be selected according to the temperature required to facilitate the migration of active ions.

The heating layer 500 may include, for example, a metallic material such as tungsten (W), cobalt (Co), molybdenum (Mo), titanium (Ti), or tantalum (Ta), or a metal nitride. The heating layer 500 may include a plurality of layers having different resistivities so as to control the amount of Joule heat generated in the heating layer 500. The material constituting the heating layer 500 may be determined in consideration of resistivity and thermal conductivity of the memory device.

The spacer layer 600 may be disposed over the gate stack 300, the insulation layer 400, and the heating layer 500, and may be a layer including an insulating material. A gate terminal 610 and a first heating terminal 620 may be disposed within the spacer layer 600. The gate terminal 610 and the first heating terminal 620 may be electrically isolated from each other in the spacer layer 600.

The first heating terminal 620 may have a circular or ring shape when viewed in a direction perpendicular to a surface of the substrate 100 (e.g., a vertical or stack direction).

The gate terminal 610 and the first heating terminal 620 may include a metallic material, such as for example, at least one of aluminum, copper, nickel, iron, chromium, titanium, zinc, lead, gold, or silver.

The gate terminal 610 may be connected to the gate lines (GL1, GL2, GL3) (see FIG. 2), and may receive a gate voltage (V_{g}) through the gate lines (GL1, GL2, GL3). In addition, the first heating terminal 620 may be connected to heating lines (HL1, HL2, HL3) (see FIG. 2), and may receive a first heating voltage (Vₕ₁) through the heating lines (HL1, HL2, HL3).

A second heating terminal 110 may be disposed within the substrate 100. The second heating terminal 110 may have a circular or ring shape when viewed in a direction perpendicular to a surface of the substrate 100 (e.g., a vertical or stack direction).

The second heating terminal 110 may include a metallic material, which may include, for example, at least one of aluminum, copper, nickel, iron, chromium, titanium, zinc, lead, gold, or silver.

The second heating terminal 110 may be connected to heating lines (HL1’, HL2’, HL3’) (see FIG. 2), and may receive a second heating voltage (Vₕ₂) through the heating lines.

The first heating voltage (Vₕ₁) and the second heating voltage (Vₕ₂) may be applied to respective ends of the heating layer 500 through the first heating terminal 620 and the second heating terminal 110, and a current may flow through the heating layer 500 due to a voltage difference.

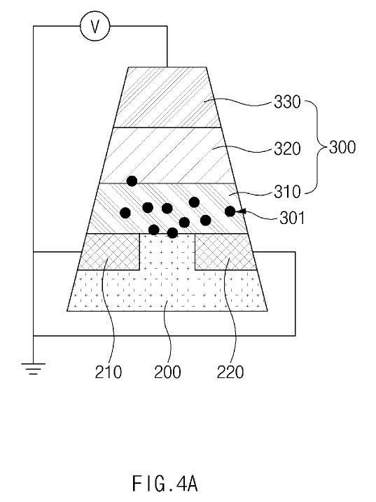

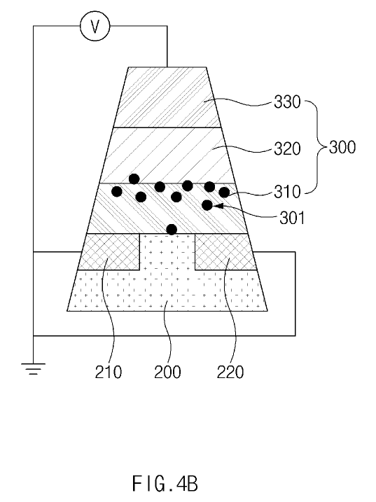

FIGS. 4A and 4B are views illustrating a method for operating a three-terminal memory device according to an embodiment of the present disclosure.

Referring to FIGS. 4A and 4B, a gate voltage may be applied to a gate electrode layer 330 included in a gate stack 300, and a source region 210 and a drain region 220 may be connected by a wire and grounded. The gate voltage may be provided to the gate electrode layer 330 by a gate voltage control circuit 10 (see FIG. 2).

FIG. 4A is a diagram illustrating a write operation in which a voltage is applied to the gate stack 300 to decrease the resistance of the memory device. As the voltage is applied to the gate stack 300, active ions 301 of an ion storage layer 320 may move to a channel region 200 through an electrolyte layer 310. Accordingly, the conductance of the channel region 200 may increase, and the resistance of the memory device may decrease. When the resistance of the memory device decreases, the current increases between the source region 210 and the drain region 220.

FIG. 4B is a diagram illustrating a write operation in which a voltage is applied to the gate stack 300 to increase the resistance of the memory device. Referring to FIG. 4B, when a voltage having a polarity opposite to that shown in FIG. 4A is applied to the gate stack 300, the active ions 301 of the channel region 200 may move toward and into the ion storage layer 320 through the electrolyte layer 310. Accordingly, the conductance of the channel region 200 decreases, and the resistance of the memory device may increase. When the resistance of the memory device increases, the effect of decreasing the current between the source region 210 and the drain region 220 may be achieved.

As illustrated in FIGS. 4A and 4B, the write operations of the electrochemical memory device may be operations accompanied by the movement of active ions 301.

After the active ions 301 move into the channel region 200 or the electrolyte layer 310, an additional period of time may be required for diffusion of the active ions 301.

During the write operation of the memory device, an amount of operation time may be required to stabilize the conductance of the channel region 200, so that the operation speed of the memory device may decrease.

The memory device according to an embodiment of the present disclosure may include a heating layer that enhances the mobility and diffusion speed of the active ions 301. When the heating layer is provided, the movement of the active ions 301 may become more active, and the time required for stabilization of the channel region 200 may be reduced.

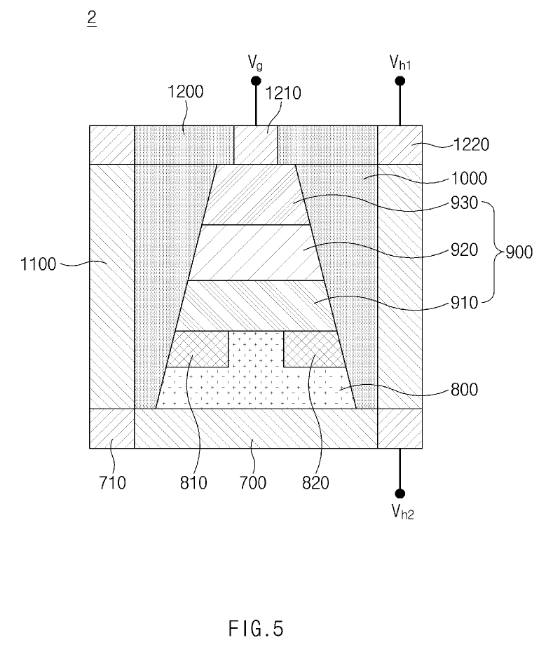

FIG. 5 is a cross-sectional view illustrating a memory device according to another embodiment of the present disclosure.

Referring to FIG. 5, a memory device 2 may include an insulation layer 1000 and a heating layer 1100, which have shapes different from those of the insulation layer and the heating layer of a memory device 1 shown in FIG. 3.

Referring to FIG. 5, a channel region 800 may be disposed over a substrate 700, and a gate stack 900 may be disposed over the channel region 800. The insulation layer 1000 may contact the sidewalls of the channel region 800 and the gate stack 900, and the heating layer 1100 may contact the sidewalls of the insulation layer 1000.

A spacer layer 1200 may be disposed over the gate stack 900, the insulation layer 1000, and the heating layer 1100.

A gate terminal 1210 may be disposed at a first side of the spacer layer 1200 and a first heating terminal 1220 may be disposed at a second side of the spacer layer 1200. A source region 810 and a drain region 820, spaced apart from each other, may be disposed within the channel region 800. A second heating terminal 710 may be disposed within the substrate 700.

The gate stack 900 may include an electrolyte layer 910 disposed over the channel region 800, an ion storage layer 920 disposed over the electrolyte layer 910, and a gate electrode layer 930 disposed over the ion storage layer 920.

The insulation layer 1000 of FIG. 5 may be tapered in the stack direction such that an upper portion has a greater width than a lower portion. In some embodiments, the active ions may move within the ion storage layer 920 and the electrolyte layer 910 included in the gate stack 900, and the channel region 800.

In some embodiments, within the memory device 2, the active ions within the channel region 800 may require the greatest amount of time to diffuse. Therefore, the operation time delay of the memory device 2 can be prevented by selectively increasing the mobility of the active ions in the channel region 800.

The memory device 2 according to an embodiment of FIG. 5 may maintain the highest temperature in the channel region 800 and the lowest temperature in the gate electrode layer 930 by reducing the thickness (i.e., width in FIG. 5) of the insulation layer 1000 toward the channel region 800.

The gate electrode layer 930 refers to a layer including a conductive material such as a metal. As the temperature of the gate electrode layer 930 rises, resistivity of the gate electrode layer 930 increases, resulting in higher power consumption during the write operation. By adjusting the thickness of the insulation layer 1000 to provide greater insulation to the gate electrode layer 930, it is possible to provide a memory device that has lower power consumption characteristics while improving the operation speed thereof.

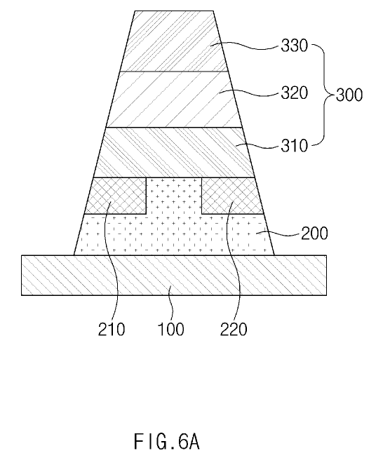

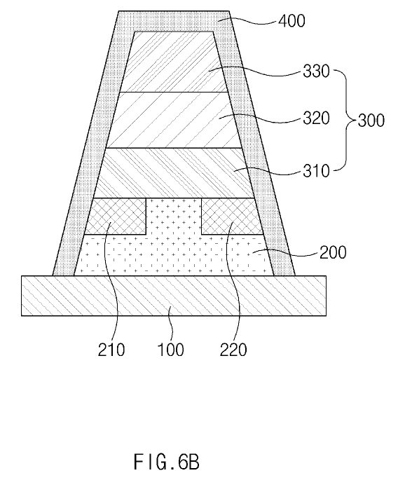

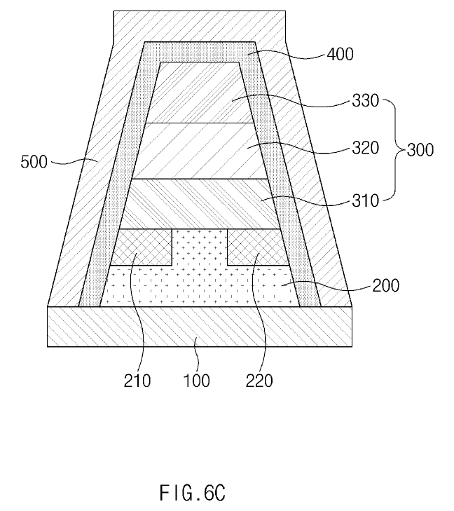

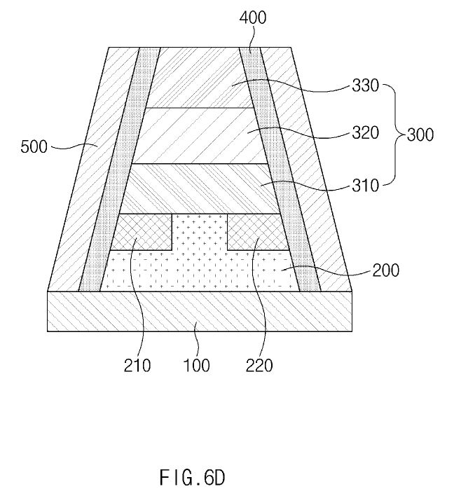

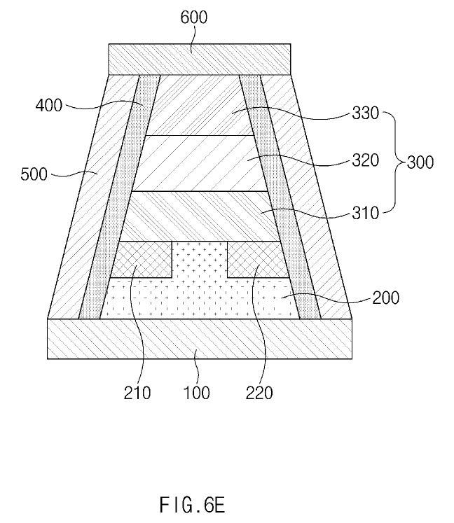

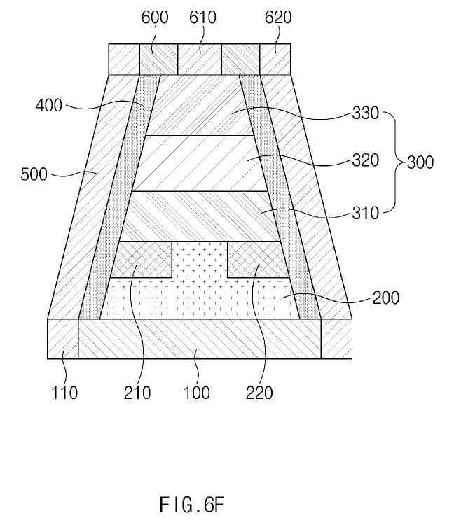

FIGS. 6A to 6F are views illustrating a method for manufacturing a memory device according to an embodiment of the present disclosure.

Referring to FIG. 6A, a channel region 200 and a gate stack 300 may be stacked over the substrate 100 in a first direction (i.e., a vertical or stack direction). A source region 210 and a drain region 220 may be formed within the channel region 200, and the gate stack 300 may include an electrolyte layer 310, an ion storage layer 320, and a gate electrode layer 330.

Referring to FIG. 6B, an insulation layer 400 may conformally surround the channel region 200 and the gate stack 300. The insulation layer 400 may surround the sidewalls of the channel region 200 and the gate stack 300, and may be formed to overlap a top portion of the gate stack 300. The insulation layer 400 may be formed through a deposition process, and may include an insulating material such as silicon oxide or silicon nitride.

Referring to FIG. 6C, a heating layer 500 may conformally overlap the insulation layer 400. The heating layer 500 may contact the sidewalls of the insulation layer 400, and may overlap the top portion of the insulation layer 400.

The heating layer 500 may include a conductive material. In some embodiments, the heating layer 500 may include multiple layers to adjust resistivity. The conductive material may, for example, include a metal.

Referring to FIG. 6D, at least a portion of the insulation layer 400 and at least a portion of the heating layer 500 may be removed. The insulation layer 400 and the heating layer 500 may be removed through an etching process.

Referring to FIG. 6E, a spacer layer 600 may be formed over the gate stack 300, the insulation layer 400, and the heating layer 500. The spacer layer 600 may be formed through a deposition process, and may include an insulating material such as silicon oxide or silicon nitride.

Referring to FIG. 6F, a gate terminal 610 and a first heating terminal 620 may be formed within the spacer layer 600, and a second heating terminal 110 may be formed within the substrate 100.

The gate terminal 610, the first heating terminal 620, and the second heating terminal 110 may include a conductive material. For example, the conductive material may be a metallic material.

The gate terminal 610 and the first heating terminal 620 may be electrically isolated from each other by the spacer layer 600.

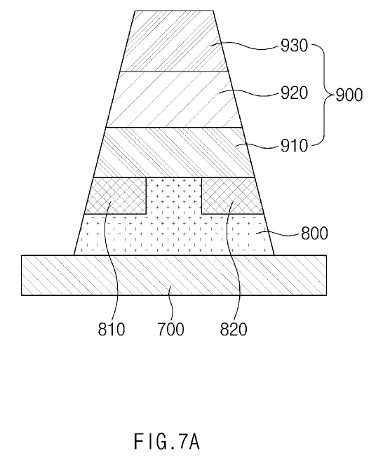

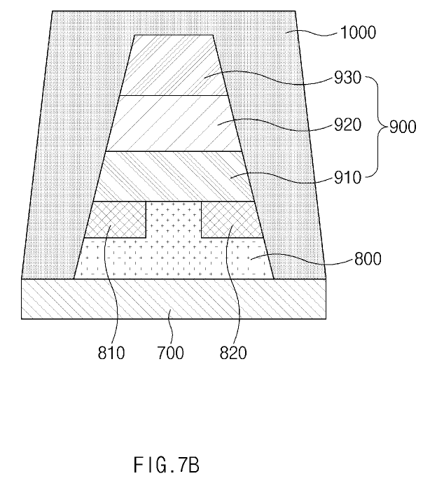

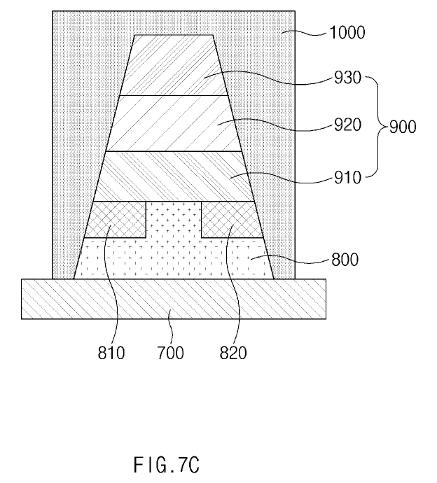

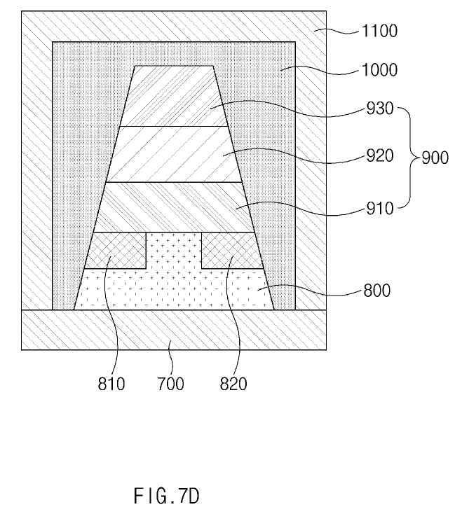

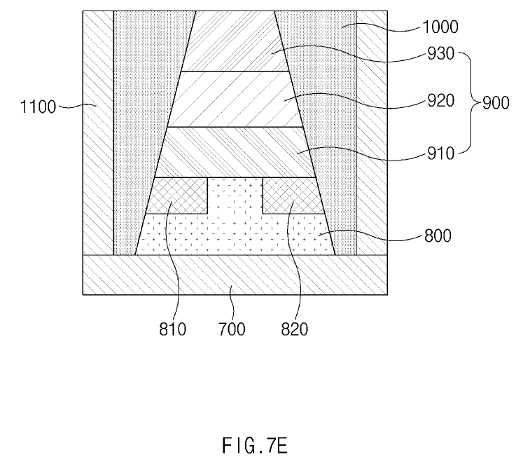

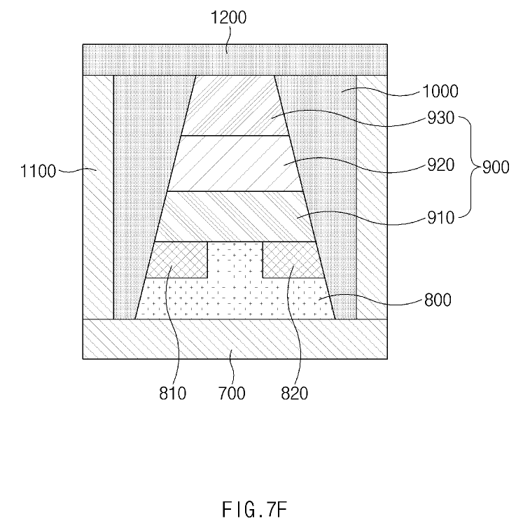

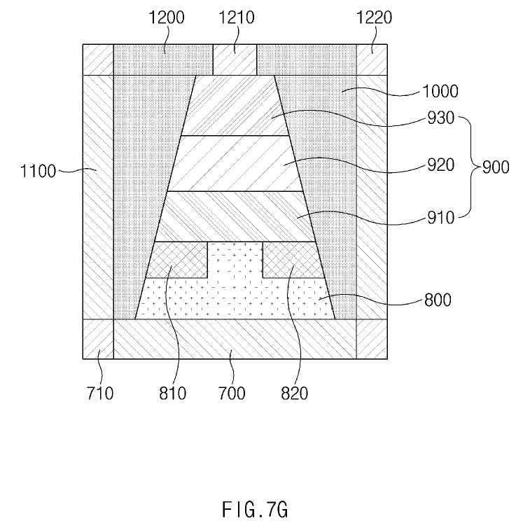

FIGS. 7A to 7G are views illustrating a method for manufacturing a memory device according to another embodiment of the present disclosure.

Referring to FIG. 7A, a channel region 800 and a gate stack 900 may be formed over a substrate 700. A source region 810 and a drain region 820 may be formed within the channel region 800, and the gate stack 900 may include an electrolyte layer 910, an ion storage layer 920, and a gate electrode layer 930.

Referring to FIG. 7B, an insulation layer 1000 may conformally surround the channel region 800 and the gate stack 900. The insulation layer 1000 may surround the sidewalls of the channel region 800 and the gate stack 900, and may be formed to overlap the top portion of the gate stack 900. The insulation layer 1000 may be formed through a deposition process, and may include an insulating material such as silicon oxide or silicon nitride.

The insulation layer 1000 of FIG. 7B may be thicker than the insulation layer 400 of FIG. 6B.

Referring to FIG. 7C, at least a portion of the insulation layer 1000 may be removed so that the width of the upper portion of the insulation layer 1000 in a horizontal direction is greater than the width of the lower portion of the insulation layer 1000.

The insulation layer 1000 may be selectively removed through the etching process.

Referring to FIG. 7D, a heating layer 1100 may conformally overlap the insulation layer 1000. The heating layer 1100 may be in contact with the sidewalls of the insulation layer 1000, and may overlap the upper portion of the insulation layer 1000.

The heating layer 1100 may include a conductive material. In some embodiments, the heating layer 1100 may include multiple layers to adjust resistivity. The conductive material may, for example, include a metal.

Referring to FIG. 7E, at least a portion of the insulation layer 1000 and at least a portion of the heating layer 1100 may be removed. The insulation layer 1000 and the heating layer 1100 may be removed through an etching process.

Referring to FIG. 7F, a spacer layer 1200 may be formed over the gate stack 900, the insulation layer 1000, and the heating layer 1100. The spacer layer 1200 may be formed through a deposition process, and may include an insulating material such as silicon oxide or silicon nitride.

Referring to FIG. 7G, a gate terminal 1210 and a first heating terminal 1220 may be formed within the spacer layer 1200, and a second heating terminal 710 may be formed within the substrate 700.

The gate terminal 1210, the first heating terminal 1220, and the second heating terminal 710 may include a conductive material. For example, the conductive material may be a metallic material.

The gate terminal 1210 and the first heating terminal 1220 may be electrically isolated from each other by the spacer layer 1200.

As is apparent from the above description, the electrochemical memory device according to embodiments of the present disclosure includes a heating circuit so that the operating speed of the memory device can be increased.

The memory device array including an electrochemical memory device according to embodiments of the present disclosure may reduce power consumption required for neuromorphic computation, thereby enabling low-power and high-efficiency on-device training.

Embodiments of the present disclosure may provide a variety of effects capable of being directly or indirectly recognized through the above-mentioned patent document.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. A memory device comprising:
a channel region disposed over a semiconductor substrate;
a gate stack disposed over the channel region;
an insulation layer configured to contact sidewalls of the channel region and the gate stack; and
a heating layer configured to contact sidewalls of the insulation layer.

2. The memory device according to claim 1, further comprising:
a source region and a drain region disposed within the channel region and spaced apart from each other.

3. The memory device according to claim 1, wherein:
the heating layer includes a resistive material.

4. The memory device according to claim 1, wherein:
the insulation layer has an upper portion that is wider than a lower portion.

5. The memory device according to claim 1, wherein:
when a heating voltage is applied to the heating layer, the heating layer generates Joule heat.

6. The memory device according to claim 5, wherein:
the insulation layer has an upper portion with the same width as a lower portion.

7. The memory device according to claim 6, wherein the gate stack includes:
an electrolyte layer disposed over the channel region;
an ion storage layer disposed over the electrolyte layer; and
a gate electrode layer disposed over the ion storage layer.

8. The memory device according to claim 7, wherein:
active ions in the ion storage layer include at least one of hydrogen ions, lithium ions, or oxygen ions.

9. The memory device according to claim 1, wherein:
when a gate voltage is applied to the gate stack and the applied gate voltage is equal to or greater than a threshold voltage, active ions move from the gate stack to the channel region.

10. A method for manufacturing a memory device comprising:
forming a channel region over a semiconductor substrate;
forming a gate stack over the channel region;
forming an insulation layer in contact with sidewalls of the channel region and the gate stack; and
forming a heating layer in contact with sidewalls of the insulation layer.

11. The method according to claim 10, further comprising:
forming a source region and a drain region spaced apart from each other within the channel region.

12. The method according to claim 10, wherein the forming the insulation layer includes:
depositing the insulation layer; and
etching at least a portion of the insulation layer such that a width of an upper portion of the insulation layer is greater than a width of a lower portion of the insulation layer.

13. The method according to claim 10, wherein the forming the gate stack includes:
forming an electrolyte layer over the channel region;
forming an ion storage layer over the electrolyte layer; and
forming a gate electrode layer over the ion storage layer.
